(19) United States
(12) Patent Application Publication
(10) Pub. No.: US 2008/0251886 A1
(43) Pub. Date: Oct. 16, 2008

(54) Fuse structure, and semiconductor device

(75) Inventor: Hirotaka Kobayashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/081,012

(22) Filed: Apr. 9, 2008

(30) Foreign Application Priority Data
Apr. 12, 2007 (JP) 2007-104688

(51) Int. Cl. H01H 37/76; H01L 21/00

(52) U.S. Cl. 257/529; 327/525; 257/E21.001

(57) ABSTRACT

A fuse structure includes a reference power layer disposed between first and second resistance-variable material layers. The first and second resistance-variable material layer may at least partially overlap each other in plan view. First and second insulating layers are disposed over and under the first and second resistance-variable material layers. A plurality of first leads is disposed over the first insulating layer. A plurality of second leads is disposed under the second insulating layer. A plurality of first via contacts penetrates the first insulating layer and connects between the first leads and the first resistance-variable material layer. A plurality of second via contacts penetrates the second insulating layer and connects between the second leads and the second resistance-variable material layer. Each of the first leads extends in a second horizontal direction that crosses a first horizontal direction in which the first and second resistance-variable material layer extend.

### BACKGROUND OF THE INVENTION

1. Field of the Invention

The present invention generally relates to a fuse structure, and a semiconductor device. More specifically, the present invention relates to a fuse structure that allows high density integration of fuses, each of which is configured to change its conductive states in accordance with an external electrical signal as well as a semiconductor device.

Priority is claimed on Japanese Patent Application No. 2007-104688, filed Apr. 12, 2007, the content of which is incorporated herein by reference.

2. Description of the Related Art

Fuses can be used for relief of a defect of a semiconductor device, the effect having been generated in manufacturing process of the semiconductor device. Fuses can also be used to change the layout of interconnection layers while changing circuit interconnection information in response to a variety of products. There has been high requirement for rewriting relief information and circuit interconnection information in a semiconductor chip as packaged, by way of input of an external electric signal into the packaged semiconductor chip. Various conventional countermeasures to satisfy this requirement have been proposed.

Japanese Unexamined Patent Application, First Publication, No. 6-310604 discloses a conventional semiconductor device including antifuses. The antifuse is a device that is designed to start with a high resistance and to permanently create an electrically conductive path by breaking an insulating layer of the antifuse, typically when the voltage exceeding a certain level is applied across the antifuse. The antifuse once created the electrically conductive path can no longer be placed again in the original highly resistive state.

Japanese Unexamined Patent Application, First Publication, No. 2005-317713 discloses a conventional semiconductor device including a phase change film that performs as a resettable fuse. The resettable fuse can be designed to be easily changed in conductivity and resettable between the highly conductive state and the highly insulative state. The phase change film is made of a phase change material. The phase change film is used as a wiring or an interconnection. A heater is provided near the phase change film. The heater changes the phase of the phase change film so as to transition a highly resistive amorphous state into a lowly resistive crystal state thereby decreasing the resistance of the phase change film or to transition the lowly resistive crystal state into the highly resistive amorphous state thereby increasing the resistance of the phase change film. The heater used to change the resistance of the phase change film results in a large size of each fuse. This publication also discloses eliminating a heater and in place using electrodes that apply a current across the phase change film, thereby generating heat at the phase change film and changing the crystal state of the phase change film. This alternating proposal simplifies the structure of the fuse that changes the crystal state of the phase change film. Such simplification of the fuse structure reduces the size of each element but insufficiently and further reduction in size of each element is required.

Japanese Unexamined Patent Application, First Publication, No. 2006-222215 discloses a conventional phase change memory that settles the problems with the difficulty in size reduction of each element. The phase change memory has a top electrode, a phase change film, and a bottom electrode plug which connects the phase change film to a bottom electrode plate as a common plate. The phase change film is made of chalcogenide. Current application to the bottom electrode plug causes heat generation which transitions between a highly resistive amorphous state and a lowly resistive crystal state, thereby realizing a bit-information-rewritable phase change memory. The plain area of the phase change element corresponds to the plain area of the bottom electrode plug. This allows high density integration of a large number of the phase change memory elements as unit elements and allows a very limited area to have many bit information.

Japanese Unexamined Patent Application, First Publication, No. 6-232271 discloses a material for interconnection which can vary electrical resistance by light irradiation, voltage application and heat application, wherein the material includes at least two elements that are selected from the group consisting of Ge, Te, Sb and In.

In accordance with the conventional phase change memory disclosed in Japanese Unexamined Patent Application, First Publication, No. 2006-222215, at least two interconnection layers partially performing as top and bottom electrodes are disposed over and under the phase change film of chalcogenide. The presence of the at least two interconnection layers as the top and bottom electrodes makes it difficult to reduce the plain area for disposing the fuse. The conventional phase change memory has the issue to further reduce the plain area for layout of the fuse and to increase the density of integration of the fuses in a limited area.

In view of the above, it will be apparent to those skilled in the art from this disclosure that there exists a need for an improved fuse structure, a semiconductor device, and a method of forming the semiconductor device. This invention addresses this need in the art as well as other needs, which will become apparent to those skilled in the art from this disclosure.

### SUMMARY OF THE INVENTION

Accordingly, it is a primary object of the present invention to provide a fuse structure.

It is another object of the present invention to provide a fuse structure that allows reduction in plain area for layout of a fuse.

It is a further object of the present invention to provide a fuse structure that allows high density integration of fuses in a limited area.

It is a still further object of the present invention to provide a semiconductor device that has a high density integration of fuses.

In accordance with a first aspect of the present invention, a fuse structure may include, but is not limited to, a first resistance-variable material layer, a second resistance-variable material layer, a reference power layer, a first insulating layer, a plurality of first leads, a plurality of first via contacts, a second insulating layer, a plurality of second leads, and a plurality of second via contacts. The first resistance-variable material layer may extend in a first horizontal direction. A second resistance-variable material layer is disposed under the first resistance-variable material layer. The first and second resistance-variable material layer may at least partially overlap each other in plan view. The reference power layer may be disposed between the first and second resistance-variable material layers. The first insulating layer may be disposed over the first resistance-variable material layer. The plurality of first leads may be disposed over the first insulating layer. Each of the first leads may extend in a second horizontal direction that crosses the first horizontal direction. The plurality of first via contacts may penetrate the first insulating layer. The plurality of first via contacts may connect between the plurality of first leads and the first resistance-variable material layer. The second insulating layer may be disposed under the second resistance-variable material layer. The plurality of second leads may be disposed under the second insulating layer. Each of the second leads may extend in the second horizontal direction. The plurality of second via contacts may penetrate the second insulating layer. The plurality of second via contacts may connect between the plurality of second leads and the second resistance-variable material layer.

In some cases, the first and second resistance-variable material layers may be made of a phase change material.

In some cases, the first and second resistance-variable material layers may be made of perovskite-type metal oxide.

In some cases, the plurality of first leads may include first and second alignments of first leads. The first and second alignments of first leads run in the first horizontal direction. The ends of the first leads belonging to the first alignment would face toward the ends of the first leads belonging to the second alignment. The plurality of second leads may include first and second alignments of second leads. The first and second alignments of second leads run in the first horizontal direction. The ends of the second leads belonging to the first alignment would face toward the ends of the second leads belonging to the second alignment.

In accordance with a second aspect of the present invention, a fuse structure may include, but is not limited to, a substrate configured to be applied with a reference power, a resistance-variable material layer, a plurality of leads, and a plurality of via contacts. The resistance-variable material layer may extend over the substrate in a first horizontal direction. The resistance-variable material layer contacts the substrate. The insulating layer may be disposed over the resistance-variable material layer. The plurality of leads may be disposed over the insulating layer. Each of the first leads may extend in a second horizontal direction that crosses the first horizontal direction. The plurality of via contacts may penetrate the insulating layer. The plurality of via contacts may connect between the plurality of leads and the resistance-variable material layer.

In some cases, the resistance-variable material layer may be made of a phase change material.

In some cases, the resistance-variable material layer may be made of perovskite-type metal oxide.

In some cases, the plurality of leads may include first and second alignments of leads. The first and second alignments of leads run in the first horizontal direction. The ends of the leads belonging to the first alignment may face toward the ends of the leads belonging to the second alignment.

In accordance with a third aspect of the present invention, a semiconductor device may include a fuse structure that has been described in the first aspect of the present invention.

In accordance with a fourth aspect of the present invention, a semiconductor device may include a fuse structure that has been described in the second aspect of the present invention.

### BRIEF DESCRIPTION OF THE DRAWINGS

Referring now to the attached drawings which form a part of this original disclosure:

FIG. 1A is a plain view illustrating a fuse structure that is provided in a semiconductor device in accordance with a first preferred embodiment of the present invention;

FIG. 1B is a fragmentary cross sectional elevation view, taken along an A-A′ line of FIG. 1A, which illustrates the fuse structure that is provided in the semiconductor device;

FIGS. 2A through 2F are fragmentary cross sectional elevation views illustrating sequential steps involved in a process for forming the fuse structure shown in FIGS. 1A and 2B;

FIG. 3A is a plain view illustrating a fuse structure that is provided in a semiconductor device in accordance with a second preferred embodiment of the present invention; and

FIG. 3B is a fragmentary cross sectional elevation view, taken along a B-B′ line of FIG. 3A, which illustrates the fuse structure that is provided in the semiconductor device.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

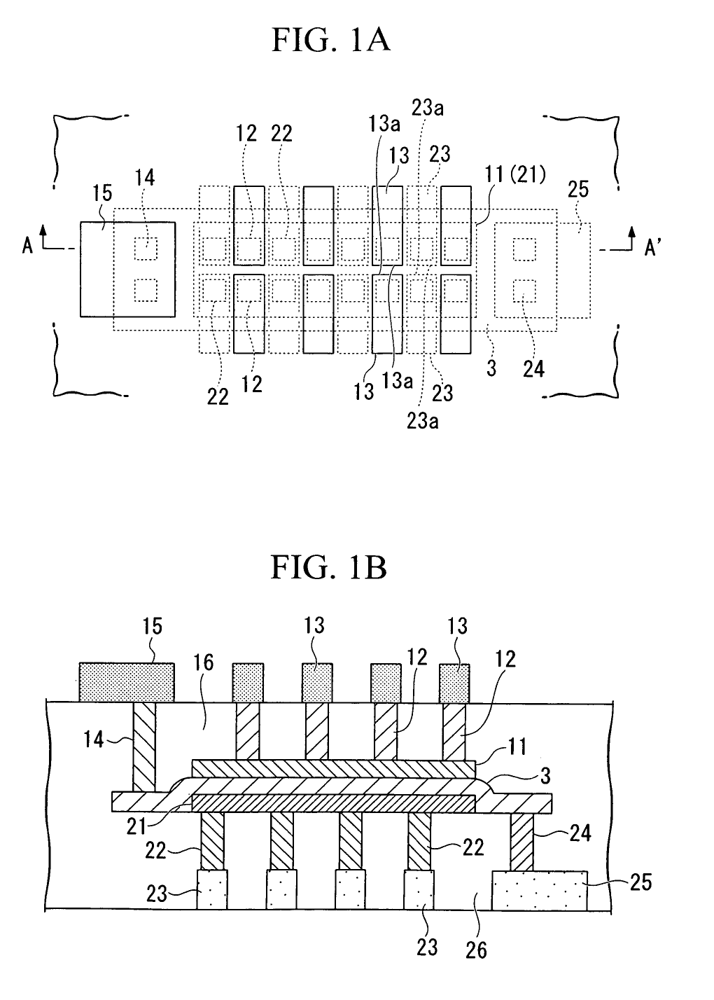

A first embodiment of the present invention will be described. FIG. 1A is a plain view illustrating a fuse structure that is provided in a semiconductor device in accordance with a first preferred embodiment of the present invention. FIG. 1B is a fragmentary cross sectional elevation view, taken along an A-A′ line of FIG. 1A, which illustrates the fuse structure that is provided in the semiconductor device.

A fuse structure may include, but is not limited to, a reference power layer 3, first and second resistance-variable material layers 11 and 21, and first and second insulating layers 16 and 26. The reference power layer 3 is disposed between the first and second resistance-variable material layers 11 and 21. The reference power layer 3 is sandwiched between the first and second resistance-variable material layers 11 and 21. A typical example of material for the reference power layer 3 may include, but is not limited to, aluminum. The reference power layer 3 has upper and lower surfaces that respectively contact the first and second resistance-variable material layers 11 and 21. The reference power layer 3 is adapted to be applied with a reference power voltage so as to allow the reference power layer 3 to perform as a common wiring for the first and second resistance-variable material layers 11 and 21. In typical cases, the first and second resistance-variable material layers 11 and 21 may overlap each other in plan view as shown in FIG. 1A. The first and second resistance-variable material layers 11 and 21 may extend in a horizontal plane. In some cases, the first and second resistance-variable material layers 11 and 21 may have a rectangular shape having a longitudinal axis that is parallel to a first horizontal direction along the A-A′ line of FIG. 1A.

In typical case, the first and second resistance-variable material layers 11 and 21 may be realized by a phase change material. A typical example of the phase change material for the first and second resistance-variable material layers 11 and 21 may include, but is not limited to, chalcogenide. Examples of chalcogenide may include, but are not limited to, two or more of germanium (Ge), antimony (Sb), tellurium (Te), and selenium (Se). A typical example of the chalcogenide may include, but is not limited to, Ge₂Sb₂Te₅.

The first resistance-variable material layer 11 has upper and lower surfaces. The lower surface of the first resistance-variable material layer 11 contacts the upper surface of the reference power layer 3. The second resistance-variable material layer 21 has upper and lower surfaces. The upper surface of the second resistance-variable material layer 21 contacts the lower surface of the reference power layer 3.

The first insulating layer 16 extends over the first resistance-variable material layer 11 and the reference power layer 3. In some cases, the first insulating layer 16 may be made of silicon oxide.

The fuse structure may further include a plurality of first leads 13. The first leads 13 extend over the first insulating layer 16. A typical example for the material of the first leads 13 may include, but is not limited to, aluminum. Each of the first leads 13 provides an electrical contact with an external device. The first leads 13 extend in a second horizontal direction perpendicular to the first horizontal direction along the A-A′ line of FIG. 1A. The first leads 13 have overlapping portions that overlap in plan view the first resistance-variable material layer 11. The overlapping portions of the first leads 13 are aligned in symmetrical to the longitudinal center axis of the first resistance-variable material layer 11, wherein the longitudinal center axis runs in the first horizontal direction along the A-A′ line of FIG. 1A. Dual alignments running in the first horizontal direction of the first leads 13 are symmetrical to the longitudinal center axis of the first resistance-variable material layer 11. The end portion 13a of the overlapping portion of each first lead 13 on one of the dual alignment faces toward the end portion 13a of the overlapping portion of each first lead 13 on another alignment. In other words, the first leads 13 on one alignment extends away from the first leads 13 on another alignment in symmetrical to the longitudinal center axis of the first resistance-variable material layer 11.

The fuse structure further includes a plurality of first via contacts 12. The first via contacts 12 are presented in the first insulating layer 16. The first via contacts 12 connect between the first resistance-variable material layer 11 and the first leads 13. The first leads 13 are electrically connected through the first via contacts 12 to the first resistance-variable material layer 11. Each of the first via contacts 12 extends in a vertical direction from the first leads 13 to the first resistance-variable material layer 11. There are a plurality of pairs of the first via contact 12 and the first lead 13. Each first lead 13 is electrically connected through the pared one of the first via contacts 12 to the first resistance-variable material layer 11. The first via contacts 12 are made of a conductive material, a typical example of which may include, but is not limited to, tungsten. The bottom portion of each first via contact 12 contacts the first resistance-variable material layer 11.

The bottom portion or the first end of each first via contact 12 can perform as a heater that heats the first resistance-variable material layer 11, thereby changing the resistance of the first resistance-variable material layer 11. Each contact portion of the first resistance-variable material layer 11 in contact with each of the first via contacts 12 performs as a fuse. The first resistance-variable material layer 11 performs as the same number of fuses as the first via contacts 12 or the first leads 13.

The fuse structure may further include a plurality of second leads 23. The second leads 23 extend under the second insulating layer 26. A typical example for the material of the second leads 23 may include, but is not limited to, aluminum. Each of the second leads 23 provides an electrical contact with an external device. The second leads 23 extend in the second horizontal direction perpendicular to the first horizontal direction along the A-A′ line of FIG. 1A. The second leads 23 have overlapping portions that overlap in plan view the second resistance-variable material layer 21. The overlapping portions of the second leads 23 are aligned in symmetrical to the longitudinal center axis of the second resistance-variable material layer 21, wherein the longitudinal center axis runs in the first horizontal direction along the A-A′ line of FIG. 1A. Dual alignments running in the first horizontal direction of the second leads 23 are symmetrical to the longitudinal center axis of the second resistance-variable material layer 21. The end portion 23a of the overlapping portion of each second lead 23 on one of the dual alignment faces toward the end portion 23a of the overlapping portion of each second lead 23 on another alignment. In other words, the second leads 23 on one alignment extends away from the second leads 23 on another alignment in symmetrical to the longitudinal center axis of the second resistance-variable material layer 21. In plan view, the first and second leads 13 and 23 are alternately aligned in the first horizontal direction so that the first and second leads 13 and 23 do not overlap each other.

The fuse structure further includes a plurality of second via contacts 22. The second via contacts 22 are presented in the second insulating layer 26. The second via contacts 22 connect between the second resistance-variable material layer 21 and the second leads 23. The second leads 23 are electrically connected through the second via contacts 22 to the second resistance-variable material layer 21. Each of the second via contacts 22 extends in a vertical direction from the second leads 23 to the second resistance-variable material layer 21. There are a plurality of pairs of the second via contact 22 and the second lead 23. Each second lead 23 is electrically connected through the pared one of the second via contacts 22 to the second resistance-variable material layer 21. The second via contacts 22 are made of a conductive material, a typical example of which may include, but is not limited to, tungsten. The top portion of each second via contact 22 contacts the second resistance-variable material layer 21.

The top portion or the first end of each second via contact 22 can perform as a heater that heats the second resistance-variable material layer 21, thereby changing the resistance of the second resistance-variable material layer 21. Each contact portion of the second resistance-variable material layer 21 in contact with each of the second via contacts 22 performs as a fuse. The second resistance-variable material layer 21 performs as the same number of fuses as the second via contacts 22 or the second leads 23.

The fuse structure further includes first and second power lines 15 and 25 and third and fourth via contacts 14 and 24. The first power line 15 extends over the first insulating layer 16. The second power line 25 extends under the second insulating layer 26. The third via contact 14 penetrates the first insulating layer 16. The third via contact 14 connects between the first power line 15 and the reference power layer 3. The fourth via contact 24 penetrates the second insulating layer 26. The fourth via contact 24 connects between the second power line 25 and the reference power layer 3.

As described above, the first resistance-variable material layer 11 performs as the same number of fuses as the first via contacts 12 or the first leads 13, while the second resistance-variable material layer 21 performs as the same number of fuses as the second via contacts 22 or the second leads 23.

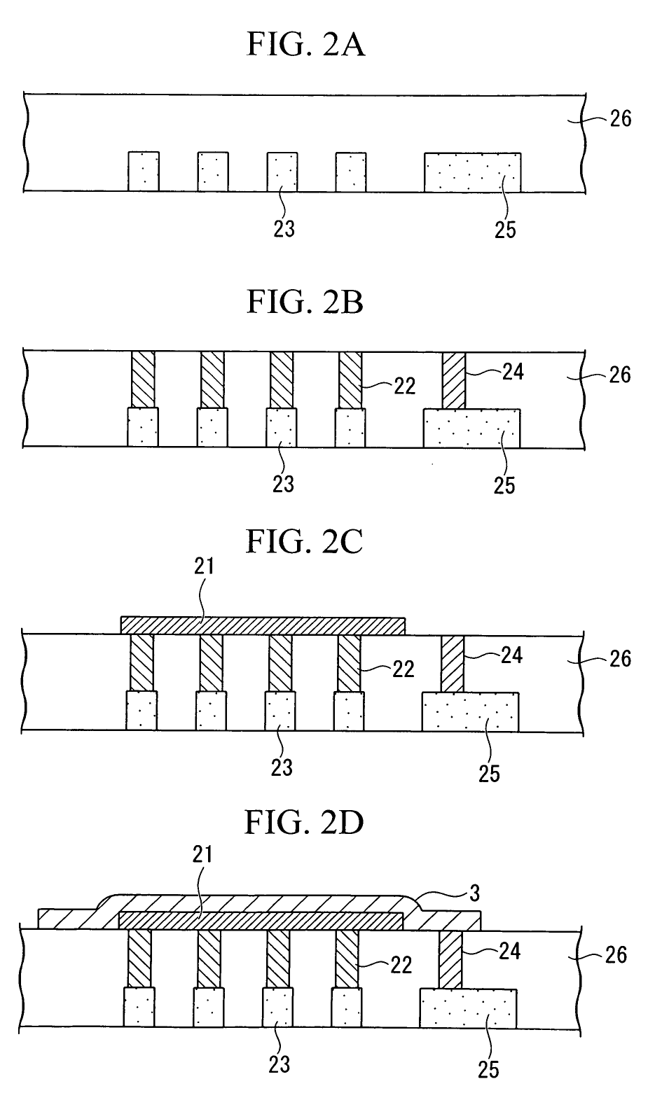

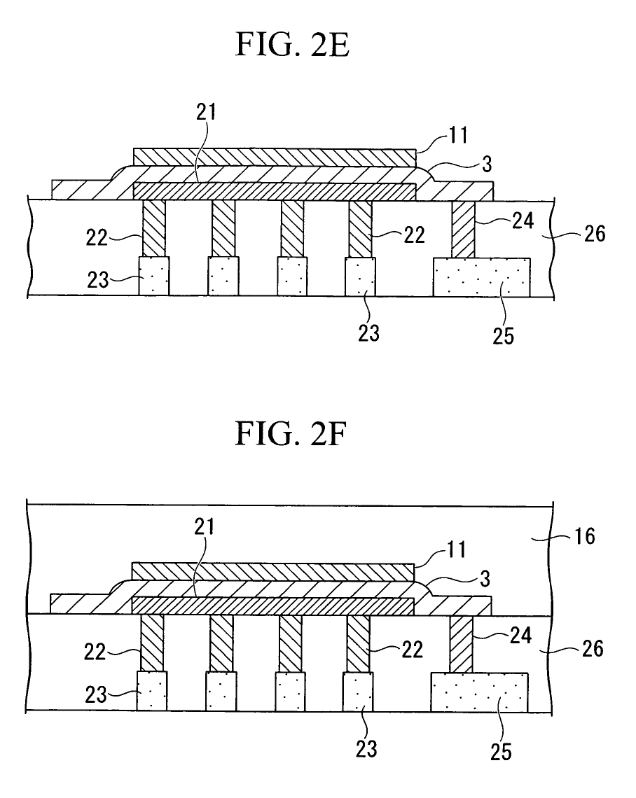

A method of forming the fuse structure of the semiconductor device of FIGS. 1A and 1B will be described with reference to FIGS. 2A through 2F. FIGS. 2A through 2F are fragmentary cross sectional elevation views illustrating sequential steps involved in a process for forming the fuse structure shown in FIGS. 1A and 2B.

In general, a metal oxide semiconductor structure and interconnections are formed over a semiconductor substrate. A fuse structure of FIGS. 1A and 1B is formed over an inter-layer insulator that extends over the metal oxide semiconductor structure and interconnections. The inter-layer insulator may be in general formed by a chemical vapor deposition process. The inter-layer insulator and other elements disposed below the inter-layer insulator are not illustrated in FIGS. 1A and 1B and 2A through 2F.

As shown in FIG. 2A, an aluminum film is formed over the interlayer insulator. The aluminum film is patterned by a photo-lithography process and a dry etching process, thereby forming a plurality of second leads 23 and a second power line 25 over the inter-layer insulator. A first silicon oxide film is formed over the second leads 23, the second power line 25, and the inter-layer insulator. The first silicon oxide film may be formed by a chemical vapor deposition process. The first silicon oxide film may be then planarized by a chemical mechanical polishing process, thereby forming a second insulating layer 26 which covers the second leads 23, the second power line 25, and the inter-layer insulator.

As shown in FIG. 2B, a photo-resist film is applied on the planarized surface of the second insulating layer 26. A photo-lithography process is carried out to form a photo-resist pattern over the planarized surface of the second insulating layer 26. A dry etching process is carried out using the photo-resist pattern as a mask to selectively etch the second insulating layer 26, thereby forming contact holes in the second insulating layer 26. The contact holes reach the second leads 23 and the second power line 25, so that parts of the second leads 23 and a part of the second power line 25 are shown through the contact holes. A tungsten film is formed in the contact holes and over the planarized surface of the second insulating layer 26. The tungsten film fills up each of the contact holes. The tungsten film contacts the second leads 23 and the second power line 25. In some cases, the tungsten film can be formed by a chemical vapor deposition process. A chemical mechanical polishing process is then carried out to selectively remove the tungsten film over the second insulating layer 26, while leaving the tungsten film in the contact holes, thereby forming a plurality of second via contacts 22 and a fourth via contact 24 in the contact holes. The second via contacts 22 contact the second leads 23. The fourth via contact 24 contacts the second power line 25.

As shown in FIG. 2C, a first phase change material film is formed over the second via contacts 22, the fourth via contact 24 and the planarized surface of the second insulating layer 26. The first phase change material film is patterned by a photo-lithography process and a dry etching process, thereby forming a second resistance-variable material layer 21 on all of the second via contacts 22 and the second insulating layer 26. The second resistance-variable material layer 21 contacts all of the second via contacts 22. The second resistance-variable material layer 21 does not extend over the fourth via contact 24. The second resistance-variable material layer 21 is electrically connected through all of the second via contacts 22 to all of the second leads 23.

As shown in FIG. 2D, an aluminum film is formed over the second resistance-variable material layer 21, the fourth via contact 24 and the planarized surface of the second insulating layer 26. The aluminum film is patterned by a photo-lithography process and a dry etching process, thereby forming a reference power layer 3. The reference power layer 3 contacts the second resistance-variable material layer 21 and the fourth via contact 24. The reference power layer 3 is eclectically connected through the second resistance-variable material layer 21 and all of the second via contacts 22 to all of the second leads 23. The reference power layer 3 is also eclectically connected through the fourth via contact 24 to the second power line 25.

As shown in FIG. 2E, a second phase change material film is formed over the reference power layer 3 and the planarized surface of the second insulating layer 26. The second phase change material film is patterned by a photo-lithography process and a dry etching process, thereby forming a first resistance-variable material layer 11 on the reference power layer 3. The first resistance-variable material layer 11 overlap in plan view the second resistance-variable material layer 21.

As shown in FIG. 2F, a second silicon oxide film is formed over the first resistance-variable material layer 11, the reference power layer 3 and the planarized surface of the second insulating layer 26. The second silicon oxide film may be formed by a chemical vapor deposition process. The second silicon oxide film may be then planarized by a chemical mechanical polishing process, thereby forming a first insulating layer 16 which covers the first resistance-variable material layer 11, the reference power layer 3 and the planarized surface of the second insulating layer 26.

With reference gain to FIG. 1B, a photo-resist film is applied on the planarized surface of the first insulating layer 16. A photo-lithography process is carried out to form a photo-resist pattern over the planarized surface of the first insulating layer 16. A dry etching process is carried out using the photo-resist pattern as a mask to selectively etch the first insulating layer 16, thereby forming contact holes in the first insulating layer 16. The contact holes reach the first resistance-variable material layer 11 and the reference power layer 3, so that parts of the first resistance-variable material layer 11 and a part of the reference power layer 3 are shown through the contact holes in the first insulating layer 16.

A tungsten film is formed in the contact holes and over the planarized surface of the first insulating layer 16. The tungsten film fills up each of the contact holes in the first insulating layer 16. The tungsten film contacts the first resistance-variable material layer 11 and the reference power layer 3. In some cases, the tungsten film can be formed by a chemical vapor deposition process. A chemical mechanical polishing process is then carried out to selectively remove the tungsten film over the first insulating layer 16, while leaving the tungsten film in the contact holes in the first insulating layer 16, thereby forming a plurality of first via contacts 12 and a third via contact 14 in the contact holes.

The first via contacts 12 contact the first resistance-variable material layer 11. The third via contact 14 contacts the reference power layer 3. An aluminum film is formed over the first via contacts 12, the third via contact 14 and the first insulating layer 16. The aluminum film is patterned by a photo-lithography process and a dry etching process, thereby forming a plurality of first leads 13 and a first power line 15. The plurality of first leads 13 contact the first via contacts 12. The plurality of first leads 13 are electrically connected through the first via contacts 12 to the first resistance-variable material layer 11. The first power line 15 contacts the third via contact 14. The first power line 15 is electrically connected through the third via contact 14 to the reference power layer 3. As a result, the fuse structure shown in FIGS. 1A and 1B is completed.

Operations of the fuse structure will be described with reference again to FIGS. 1A and 1B. A current is applied across the first resistance-variable material layer 11 between the reference power layer 3 and the plurality of first leads 13, so as to change the resistance of the first resistance-variable material layer 11. Also a current is applied across the second resistance-variable material layer 21 between the reference power layer 3 and the plurality of second leads 23, so as to change the resistance of the second resistance-variable material layer 21. A pulse of current applied to each of the first leads 13 can be adjusted so as to control heat generation at the contact portions of the first via contacts 12, wherein the contact portions contact the first resistance-variable material layer 11. The contact portion of each of the first via contacts 12 performs as a first heater. A pulse of current applied to each of the second leads 23 can be adjusted so as to control heat generation at the contact portions of the second via contacts 22, wherein the contact portions contact the second resistance-variable material layer 21. The contact portion of each of the second via contacts 22 performs as a second heater.

The current application to the first leads 13 heats contact portions of the first resistance-variable material layer 11, wherein the contact portions contact with the first via contacts 12. Separate adjustment of the application of the current to each first lead 13 can separately control the temperature of each contact portion of the first resistance-variable material layer 11 in contact with the first via contact 12. Separate control of the temperature of each contact portion of the first resistance-variable material layer 11 can separately control the crystal state of each contact portion of the first resistance-variable material layer 11 in contact with the first via contact 12. Separate control of the crystal state of each contact portion of the first resistance-variable material layer 11 can separately control the contact resistance between each contact portion of the first resistance-variable material layer 11 and each first via contact 12.

Also, the current application to the second leads 23 heats contact portions of the second resistance-variable material layer 21, wherein the contact portions contact with the second via contacts 22. Separate adjustment of the application of the current to each second lead 23 can separately control the temperature of each contact portion of the second resistance-variable material layer 21 in contact with the second via contact 22. Separate control of the temperature of each contact portion of the second resistance-variable material layer 21 can separately control the crystal state of each contact portion of the second resistance-variable material layer 21 in contact with the second via contact 22. Separate control of the crystal state of each contact portion of the second resistance-variable material layer 21 can separately control the contact resistance between each contact portion of the second resistance-variable material layer 21 and each second via contact 22.

In some cases, the pulse current applied through each first lead 13 and the first via contact 12 to the first resistance-variable material layer 11 can be adjusted in pulse width and pulse height to control the crystal state of the contact portion of the first resistance-variable material layer 11, thereby controlling the resistance of the contact portion of the first resistance-variable material layer 11. Also, the pulse current applied through each second lead 23 and the second via contact 22 to the second resistance-variable material layer 21 can be adjusted in pulse width and pulse height to control the crystal state of the contact portion of the second resistance-variable material layer 21, thereby controlling the resistance of the contact portion of the second resistance-variable material layer 21.

When a pulse of current with a lower pulse height and a wider pulse width is applied through the first lead 13 and the first via contact 12 to the first resistance-variable material layer 11, crystallization is caused at the phase change material of the contact portion of the first resistance-variable material layer 11 in contact with the first via contact 12, thereby decreasing the resistance of the contact portion of the first resistance-variable material layer 11. Also, when a pulse of current with a lower pulse height and a wider pulse width is applied through the second lead 23 and the second via contact 22 to the second resistance-variable material layer 21, crystallization is caused at the phase change material of the contact portion of the second resistance-variable material layer 21 in contact with the second via contact 22, thereby decreasing the resistance of the contact portion of the second resistance-variable material layer 21.

When a pulse of current with a higher pulse height and a narrower pulse width is applied through the first lead 13 and the first via contact 12 to the first resistance-variable material layer 11, amorphization is caused at the phase change material of the contact portion of the first resistance-variable material layer 11 in contact with the first via contact 12, thereby increasing the resistance of the contact portion of the first resistance-variable material layer 11. Also, when a pulse of current with a higher pulse height and a narrower pulse width is applied through the second lead 23 and the second via contact 22 to the second resistance-variable material layer 21, amorphization is caused at the phase change material of the contact portion of the second resistance-variable material layer 21 in contact with the second via contact 22, thereby increasing the resistance of the contact portion of the second resistance-variable material layer 21.

Namely, adjustments in pulse width and height of the pulse current can control the transition of the phase or the crystal state of the contact portion of the first resistance-variable material layer 11, thereby changing the resistance of the contact portion of the first resistance-variable material layer 11. Also, adjustments in pulse width and height of the pulse current can control the transition of the phase or the crystal state of the contact portion of the second resistance-variable material layer 21, thereby changing the resistance of the contact portion of the second resistance-variable material layer 21.

Therefore, the fuse structure is configured to change the resistance between the reference power layer 3 and each of the first leads 13 as well as change the resistance between the reference power layer 3 and each of the second leads 23. Application of external electric signal through the first leads 13 through the first via contacts 12 to the first resistance-variable material layer 11 as well as another application of external electric signal through the second leads 23 through the second via contacts 22 to the second resistance-variable material layer 21 can rewrite relief information and circuit interconnection information in a semiconductor device.

The fuse structure includes the reference power layer 3 that is disposed between the first and second resistance-variable material layers 11 and 21. The fuse structure is configured to allow that the reference power layer 3 is commonly used in changing the resistance of either one or both of the first and second resistance-variable material layers 11 and 21. The fuse structure has upper and lower two-dimensional alignments of fuses on the upper and lower surfaces of the reference power layer 3. This fuse structure allows increased density of integration of the fuses.

Differently from the above-described fuse structure, it is assumed that first and second reference power layers are separately provided for the first and second resistance-variable material layers 11 and 21 respectively, instead of the commonly used singe reference power layer 3. In this case, the first and second reference power layers can be disposed so that the first and second reference power layers do not overlap each other, thereby resulting in decreased density of integration of the fuses. In other case, the first and second reference power layers can be disposed so that the first and second reference power layers overlap each other, thereby increasing two times the number of multi-level of the layers. The multi-layered structure of the reference power layers decreases the flexibility in layout of the fuses. Further, the multi-layered structure of the reference power layers needs additional via contact and additional interconnection for the second reference power layer, resulting in increased necessary plain-area of the fuse structure. The multi-layered structure of the reference power layers results in decreased density of integration of fuses.

The above-described fuse structure includes the single reference power layer that is commonly used for changing the resistances of both the first and second resistance-variable material layers 11 and 21. The above-described fuse structure does not need any additional reference power layer for the second resistance-variable material layer 21. The above-described fuse structure does not need any additional via contact and additional interconnection for the second reference power layer, resulting in no increase in plain-area of the fuse structure. The above-described fuse structure allows increased density of integration of fuses. The above-described fuse structure increases the flexibility in layout of the fuses and the density of integration of the fuses. The above-described fuse structure makes it easier to form or manufacture the semiconductor device including the highly dense integration of the fuses.

The above-described fuse structure is configured to allow that the first resistance-variable material layer 11 performs as the same number of fuses as the first via contacts 12 or the first leads 13, while the second resistance-variable material layer 21 performs as the same number of fuses as the second via contacts 22 or the second leads 23. The above-described fuse structure has the multi-level two-dimensional alignments of the fuses using the commonly used single reference power layer 3. Thus, the above-described fuse structure allows for increasing the density of integration of the fuses two times as compared to the conventional fuse structure that has a single pair of the single reference power layer and the single resistance-variable material layer.

The above-described fuse structure has the upper two-dimensional alignment of the first leads 13 and the lower two-dimensional alignment of the second fuse leads 26. The upper two-dimensional alignment of the first leads 13 is dual alignments of the first leads 13, wherein each alignment extends in the first horizontal direction along the A-A′ line of FIG. 1A, and each first lead 13 extends in the second horizontal direction that is perpendicular to the first horizontal direction. The end portion 13a of the overlapping portion of each first lead 13 on one of the dual alignment faces toward the end portion 13a of the overlapping portion of each first lead 13 on another alignment. In other words, the first leads 13 on one alignment extends away from the first leads 13 on another alignment in symmetrical to the longitudinal center axis of the first resistance-variable material layer 11. This alignment of the first leads 13 allows further increase in density of integration of the fuses.

The lower two-dimensional alignment of the second leads 23 is dual alignments of the second leads 23, wherein each alignment extends in the first horizontal direction along the A-A′ line of FIG. 1A, and each second lead 23 extends in the second horizontal direction that is perpendicular to the first horizontal direction. The end portion 23a of the overlapping portion of each second lead 23 on one of the dual alignment faces toward the end portion 23a of the overlapping portion of each second lead 23 on another alignment. In other words, the second leads 23 on one alignment extends away from the second leads 23 on another alignment in symmetrical to the longitudinal center axis of the second resistance-variable material layer 21. This alignment of the first leads 13 allows further increase in density of integration of the fuses.

The materials available for the first and second resistance-variable material layers 11 and 21 may include, but are not limited to, the phase change materials, and other materials that vary in its resistivity upon heat application thereto by current application. Examples of the materials available for the first and second resistance-variable material layer 11 and 21 may include, but are not limited to, materials that vary in its resistivity upon application of a voltage or a current thereto, and the materials such as perovskite-type metal oxide that maintain the changed resistivity even after the voltage or current application was discontinued.

The materials available for the first and second leads 13 and 23, the first to fourth via contacts 12, 22, 14, and 24 as well as the first and second power lines 15 and 25 may be conductive materials such as metals, typical examples of which may include, but are not limited to, the above-described metal, aluminum and copper. Where a high temperature heat treatment is carried out after the fuse structure has been formed, the materials available for the first and second leads 13 and 23, the first to fourth via contacts 12, 22, 14, and 24 as well as the first and second power lines 15 and 25 may be any one of refractory metals such as tungsten.

### Second Embodiment

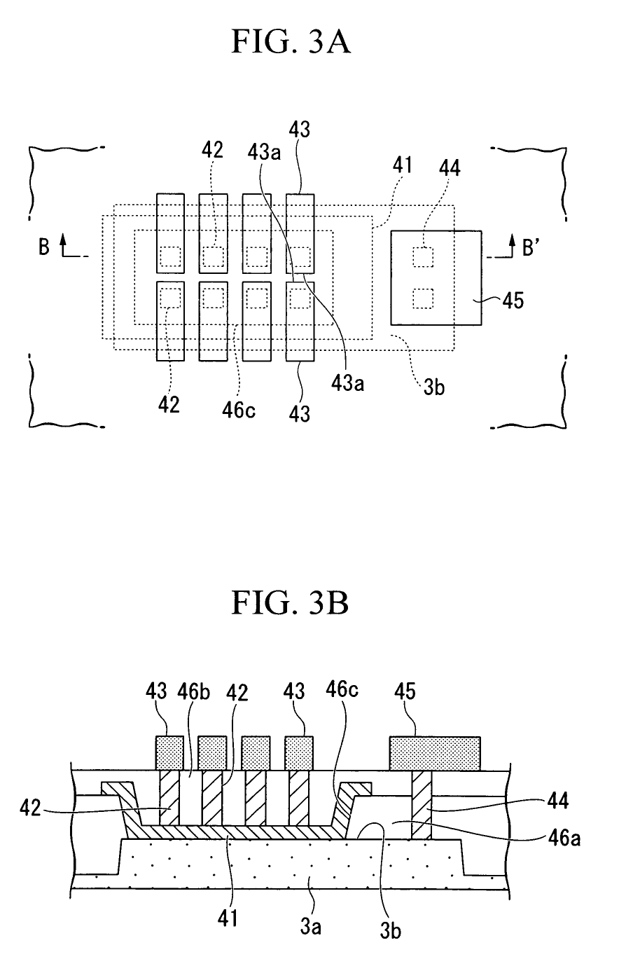

A second embodiment of the present invention will be described. FIG. 3A is a plain view illustrating a fuse structure that is provided in a semiconductor device in accordance with a second preferred embodiment of the present invention. FIG. 3B is a fragmentary cross sectional elevation view, taken along a B-B′ line of FIG. 3A, which illustrates the fuse structure that is provided in the semiconductor device.

A fuse structure shown in FIGS. 3A and 3B may include, but is not limited to, a substrate 3a, to which a reference power is applied. A typical example of the substrate 3a may be a silicon substrate. The substrate 3a has an active region 3b.

Further, the fuse structure may include, but is not limited to, a first inter-layer insulator 46a that is disposed over the substrate 3a. A typical example of material for the first inter-layer insulator 46a may include, but is not limited to, silicon oxide. The first inter-layer insulator 46a has a substrate contact hole 46c that is positioned over a part of the active region 3b of the substrate 3a. The substrate contact hole 46c penetrates the first inter-layer insulator 46a and reaches the part of the active region 3b of the substrate 3a.

Further, the fuse structure may include, but is not limited to, a resistance-variable material layer 41 that extends on the bottom and inner walls of the substrate contact hole 46c as well as extends over a peripheral portion of the upper surface of the first inter-layer insulator 46a. The peripheral portion of the upper surface is adjacent to the opening of the substrate contact hole 46c. The resistance-variable material layer 41 contacts the part of the active region 3b of the substrate 3a at the bottom of the substrate contact hole 46c.

The opening of the substrate contact hole 46c has a longitudinal center axis that extends in a first horizontal direction along the B-B line of FIG. 3A. Also, the resistance-variable material layer 41 has a longitudinal center axis that extends in the first horizontal direction.

In some cases, the resistance-variable material layer 41 may be made of the same material as the first and second resistance-variable material layer 11 and 21 that have been described in the first embodiment.

Further, the fuse structure may include, but is not limited to, a second inter-layer insulator 46b that extends over the resistance-variable material layer 41 and the first inter-layer insulator 46a. The second inter-layer insulator 46b has a plurality of contact holes that penetrate the second inter-layer insulator 46b and reaches the resistance-variable material layer 41.

The fuse structure may further include, but is not limited to, a plurality of leads 43. The leads 43 extend over the second inter-layer insulator 46b. A typical example for the material of the leads 43 may include, but is not limited to, aluminum. Each of the leads 43 provides an electrical contact with an external device. The leads 43 extend in a second horizontal direction perpendicular to the first horizontal direction along the A-A′ line of FIG. 1A. The leads 43 have overlapping portions that overlap in plan view the resistance-variable material layer 41. The overlapping portions of the leads 43 are aligned in symmetrical to the longitudinal center axis of the resistance-variable material layer 41, wherein the longitudinal center axis runs in the first horizontal direction along the A-A′ line of FIG. 1A. Dual alignments running in the first horizontal direction of the leads 43 are symmetrical to the longitudinal center axis of the resistance-variable material layer 41. The end portion 43a of the overlapping portion of each lead 43 on one of the dual alignment faces toward the end portion 43a of the overlapping portion of each lead 43 on another alignment. In other words, the leads 43 on one alignment extends away from the leads 43 on another alignment in symmetrical to the longitudinal center axis of the resistance-variable material layer 41.

The fuse structure may further include, but is not limited to, a plurality of via contacts 42 in the contact holes in the second inter-layer insulator 46b. The via contacts 42 are presented in the second insulating layer 46b. The via contacts 42 connect between the resistance-variable material layer 41 and the leads 43. The leads 43 are electrically connected through the via contacts 42 to the resistance-variable material layer 41. Each of the via contacts 42 extends in a vertical direction from the leads 43 to the resistance-variable material layer 41. There are a plurality of pairs of the via contact 42 and the lead 43. Each lead 43 is electrically connected through the pared one of the via contacts 42 to the resistance-variable material layer 41. The via contacts 42 are made of a conductive material, a typical example of which may include, but is not limited to, tungsten. The bottom portion of each via contact 42 contacts the resistance-variable material layer 41.

The bottom portion of each via contact 42 can perform as a heater that heats the resistance-variable material layer 41, thereby changing the resistance of the resistance-variable material layer 41. Each contact portion of the resistance-variable material layer 41 in contact with each of the via contacts 42 performs as a fuse. The resistance-variable material layer 41 performs as the same number of fuses as the via contacts 42 or the leads 43.

The fuse structure may further include, but is not limited to, a power line 45 and a via contact 44. The power line 45 extends over the second insulating layer 46b. The via contact 44 penetrates the second insulating layer 46b. The via contact 44 connects between the power line 45 and the substrate 3a to which the reference power is applied.

As described above, the resistance-variable material layer 41 performs as the same number of fuses as the via contacts 42 or the leads 43.

A method of forming the fuse structure of the semiconductor device of FIGS. 3A and 3B will be described.

A silicon substrate 3a is prepared. An isolation structure is formed on the surface of the silicon substrate 3a, while defining an active region 3b. A silicon oxide film is formed over the silicon substrate 3a by a chemical vapor deposition process. A chemical mechanical polishing process is carried out to planarize the surface of the silicon oxide film, thereby forming a first inter-layer insulator 46a over the silicon substrate 3a.

A photo-resist film is applied on the planarized surface of the first inter-layer insulator 46a. A photo-lithography process is carried out to form a photo-resist pattern over the planarized surface of the first inter-layer insulator 46a. A dry etching process is carried out using the photo-resist pattern as a mask to selectively etch the first inter-layer insulator 46a, thereby forming a substrate contact hole 46c in the first inter-layer insulator 46a. The substrate contact hole 46c penetrates the substrate contact hole 46c. The substrate contact hole 46c reaches a part of the active region 3b of the substrate 3a, so that the part of the active region 3b is shown through the substrate contact hole 46c.

A phase change material film is formed over the top surface of the substrate contact hole 46c and the bottom and inner walls of the substrate contact hole 46c, so that the phase change material film contacts the part of the active region 3b of the substrate 3a. A photo-resist film is applied on the phase change material film. A photo-lithography process is carried out to form a photo-resist pattern over the phase change material film. A dry etching process is carried out using the photo-resist pattern as a mask to selectively remove the phase change material film, thereby forming a resistance-variable material layer 41. The resistance-variable material layer 41 contacts the part of the active region 3b of the silicon substrate 3a.

A silicon oxide film is formed over the resistance-variable material layer 41 and the first inter-layer insulator 46a by a chemical vapor deposition process. A chemical mechanical polishing process is carried out to planarize the surface of the silicon oxide film, thereby forming a second inter-layer insulator 46b over the resistance-variable material layer 41 and the first inter-layer insulator 46a.

A photo-resist film is applied on the planarized surface of the second inter-layer insulator 46b. A photo-lithography process is carried out to form a photo-resist pattern over the planarized surface of the second inter-layer insulator 46b. A dry etching process is carried out using the photo-resist pattern as a mask to selectively etch the second inter-layer insulator 46b, thereby forming a plurality of contact holes that penetrate the second inter-layer insulator 46b and reach the resistance-variable material layer 41 as well as forming a contact hole that penetrates the first and second inter-layer insulators 46a and 46b and reaches the active region 3b that is not covered by the resistance-variable material layer 41.

A chemical vapor deposition process is carried out to form a tungsten film over the second inter-layer insulator 46b and in the contact holes in the second inter-layer insulator 46b. The tungsten film extends over the second inter-layer insulator 46b and fills up each of the contact holes in the second inter-layer insulator 46b. The tungsten film contacts the resistance-variable material layer 41 and the active region 3b of the silicon substrate 3a. A chemical mechanical polishing process is carried out to remove the tungsten film over the second inter-layer insulator 46b, while leaving the tungsten film in the contact holes, thereby forming via contacts 42 and 44. The via contacts 42 penetrate the second inter-layer insulator 46b and reach the resistance-variable material layer 41. The via contacts 42 contact the resistance-variable material layer 41. The via contact 44 penetrates the first and second inter-layer insulators 46a and 46b and reaches the active region 3b that is not covered by the resistance-variable material layer 41. The via contact 44 contacts the active region 3b of the silicon substrate 3a.

An aluminum film is formed over the second inter-layer insulator 46b and the via contacts 42 and 44. A photo-resist film is applied on the aluminum film. A photo-lithography process is carried out to form a photo-resist pattern over the aluminum film. A dry etching process is carried out using the photo-resist pattern as a mask to selectively remove the aluminum film, thereby forming leads 43 and a power line 45. The leads 43 contact via contacts 42. The leads 43 are electrically connected through the via contacts 42 to the resistance-variable material layer 41. The power line 45 contacts the via contact 44. The power line 45 is electrically connected through the via contact 44 to the active region 3b of the silicon substrate 3a.

The leads 43 extend over the second inter-layer insulator 46b. Each of the leads 43 provides an electrical contact with an external device. The leads 43 extend in the second horizontal direction perpendicular to the first horizontal direction along the A-A′ line of FIG. 1A. The leads 43 have overlapping portions that overlap in plan view the resistance-variable material layer 41. The overlapping portions of the leads 43 are aligned in symmetrical to the longitudinal center axis of the resistance-variable material layer 41, wherein the longitudinal center axis runs in the first horizontal direction along the A-A′ line of FIG. 1A. Dual alignments running in the first horizontal direction of the leads 43 are symmetrical to the longitudinal center axis of the resistance-variable material layer 41. The end portion 43a of the overlapping portion of each lead 43 on one of the dual alignment faces toward the end portion 43a of the overlapping portion of each lead 43 on another alignment. In other words, the leads 43 on one alignment extends away from the leads 43 on another alignment in symmetrical to the longitudinal center axis of the resistance-variable material layer 41.

Operations of the fuse structure will be described with reference again to FIGS. 3A and 3B. A current is applied across the resistance-variable material layer 41 between the substrate 3a and the plurality of leads 43, so as to change the resistance of the resistance-variable material layer 41. A pulse of current applied to each of the leads 43 can be adjusted so as to control heat generation at the contact portions of the via contacts 42, wherein the contact portions contact the resistance-variable material layer 41. The contact portion of each of the via contacts 42 performs as a heater.

The current application to the leads 43 heats contact portions of the resistance-variable material layer 41, wherein the contact portions contact with the via contacts 42. Separate adjustment of the application of the current to each lead 43 can separately control the temperature of each contact portion of the resistance-variable material layer 41 in contact with the via contact 42. Separate control of the temperature of each contact portion of the resistance-variable material layer 41 can separately control the crystal state of each contact portion of the resistance-variable material layer 41 in contact with the via contact 42. Separate control of the crystal state of each contact portion of the resistance-variable material layer 41 can separately control the contact resistance between each contact portion of the resistance-variable material layer 41 and each via contact 42.

In some cases, the pulse current applied through each lead 43 and the via contact 42 to the resistance-variable material layer 41 can be adjusted in pulse width and pulse height to control the crystal state of the contact portion of the resistance-variable material layer 41, thereby controlling the resistance of the contact portion of the resistance-variable material layer 41.

When a pulse of current with a lower pulse height and a wider pulse width is applied through the lead 43 and the via contact 42 to the resistance-variable material layer 41, crystallization is caused at the phase change material of the contact portion of the resistance-variable material layer 41 in contact with the via contact 42, thereby decreasing the resistance of the contact portion of the resistance-variable material layer 41.

When a pulse of current with a higher pulse height and a narrower pulse width is applied through the lead 43 and the via contact 42 to the resistance-variable material layer 41, amorphization is caused at the phase change material of the contact portion of the resistance-variable material layer 41 in contact with the via contact 42, thereby increasing the resistance of the contact portion of the resistance-variable material layer 41.

Namely, adjustments in pulse width and height of the pulse current can control the transition of the phase or the crystal state of the contact portion of the resistance-variable material layer 41, thereby changing the resistance of the contact portion of the resistance-variable material layer 41.

Therefore, the fuse structure is configured to change the resistance between each of the leads 43 and the substrate 3a to which the reference power is applied. Application of external electric signal through the leads 43 through the via contacts 42 to the resistance-variable material layer 41 can rewrite relief information and circuit interconnection information in a semiconductor device.

The above-described fuse structure includes the silicon substrate 3a to which the reference power is applied and the resistance-variable material layer 41 that contact with the active region 3b of the silicon substrate 3a. The above-described fuse structure does not need any reference power layer for the resistance-variable material layer 41. The above-described fuse structure does not need any additional via contact and additional interconnection between the resistance-variable material layer 41 and the silicon substrate 3a to which the reference power is applied, because the resistance-variable material layer 41 contacts the active region 3b of the silicon substrate 3a, resulting in no increase in size of the fuse structure. The above-described fuse structure allows increased density of integration of fuses. The above-described fuse structure increases the flexibility in layout of the fuses and the density of integration of the fuses. The above-described fuse structure makes it easier to form or manufacture the semiconductor device including the highly dense integration of the fuses.

The above-described fuse structure has the upper two-dimensional alignment of the leads 43. The upper two-dimensional alignment of the leads 43 is dual alignments of the leads 43, wherein each alignment extends in the first horizontal direction along the A-A′ line of FIG. 3A, and each lead 43 extends in the second horizontal direction that is perpendicular to the first horizontal direction. The end portion 43a of the overlapping portion of each lead 43 on one of the dual alignment faces toward the end portion 43a of the overlapping portion of each lead 43 on another alignment. In other words, the leads 43 on one alignment extends away from the leads 43 on another alignment in symmetrical to the longitudinal center axis of the resistance-variable material layer 41. This alignment of the leads 43 allows further increase in density of integration of the fuses.

The materials available for the resistance-variable material layer 41 may include, but are not limited to, the phase change materials, and other materials that vary in its resistivity upon heat application thereto by current application. Examples of the materials available for the resistance-variable material layer 41 may include, but are not limited to, materials that vary in its resistivity upon application of a voltage or a current thereto, and the materials such as perovskite-type metal oxide that maintain the changed resistivity even after the voltage or current application was discontinued.

The materials available for the leads 43, the via contacts 42 and 44 as well as the power line 45 may be conductive materials such as metals, typical examples of which may include, but are not limited to, the above-described metal, aluminum and copper. Where a high temperature heat treatment is carried out after the fuse structure has been formed, the materials available for the leads 43, the via contacts 42 and 44 as well as the power line 45 may be any one of refractory metals such as tungsten.

The above-described fuse structures can be applicable to any semiconductor devices that need to rewrite relief information and circuit interconnection information after packaged, by way of input of an external electric signal into the packaged semiconductor device.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device includes hardware and/or software that is constructed and/or programmed to carry out the desired function.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A fuse structure comprising:
a first resistance-variable material layer that extends in a first horizontal direction;
a second resistance-variable material layer under the first resistance-variable material layer, the first and second resistance-variable material layer at least partially overlapping each other in plan view,
a reference power layer disposed between the first and second resistance-variable material layers;
a first insulating layer over the first resistance-variable material layer;
a plurality of first leads over the first insulating layer, each of the first leads extending in a second horizontal direction that crosses the first horizontal direction;
a plurality of first via contacts that penetrate the first insulating layer, the plurality of first via contacts connecting between the plurality of first leads and the first resistance-variable material layer;
a second insulating layer under the second resistance-variable material layer;
a plurality of second leads under the second insulating layer, each of the second leads extending in the second horizontal direction; and
a plurality of second via contacts that penetrate the second insulating layer, the plurality of second via contacts connecting between the plurality of second leads and the second resistance-variable material layer.

2. The fuse structure according to claim 1, wherein the first and second resistance-variable material layers are made of a phase change material.

3. The fuse structure according to claim 1, wherein the first and second resistance-variable material layers are made of perovskite-type metal oxide.

4. The fuse structure according to claim 1, wherein the plurality of first leads comprises first and second alignments of first leads, the first and second alignments of first leads run in the first horizontal direction, and the ends of the first leads belonging to the first alignment face toward the ends of the first leads belonging to the second alignment, and
wherein the plurality of second leads comprises first and second alignments of second leads, the first and second alignments of second leads run in the first horizontal direction, and the ends of the second leads belonging to the first alignment face toward the ends of the second leads belonging to the second alignment.

5. A fuse structure comprising:
a substrate configured to be applied with a reference power;
a resistance-variable material layer that extends over the substrate in a first horizontal direction, the resistance-variable material layer contacting the substrate;
an insulating layer over the resistance-variable material layer;
a plurality of leads over the insulating layer, each of the first leads extending in a second horizontal direction that crosses the first horizontal direction; and
a plurality of via contacts that penetrate the insulating layer, the plurality of via contacts connecting between the plurality of leads and the resistance-variable material layer.

6. The fuse structure according to claim 5, wherein the resistance-variable material layer is made of a phase change material.

7. The fuse structure according to claim 5, wherein the resistance-variable material layer is made of perovskite-type metal oxide.

8. The fuse structure according to claim 5; wherein the plurality of leads comprises first and second alignments of leads, the first and second alignments of leads run in the first horizontal direction, and the ends of the leads belonging to the first alignment face toward the ends of the leads belonging to the second alignment.

9. A semiconductor device including a fuse structure, the fuse structure comprising:
a first resistance-variable material layer that extends in a first horizontal direction;
a second resistance-variable material layer under the first resistance-variable material layer, the first and second resistance-variable material layer at least partially overlapping each other in plan view,
a reference power layer disposed between the first and second resistance-variable material layers;
a first insulating layer over the first resistance-variable material layer;
a plurality of first leads over the first insulating layer, each of the first leads extending in a second horizontal direction that crosses the first horizontal direction;
a plurality of first via contacts that penetrate the first insulating layer, the plurality of first via contacts connecting between the plurality of first leads and the first resistance-variable material layer;
a second insulating layer under the second resistance-variable material layer;
a plurality of second leads under the second insulating layer, each of the second leads extending in the second horizontal direction; and
a plurality of second via contacts that penetrate the second insulating layer, the plurality of second via contacts connecting between the plurality of second leads and the second resistance-variable material layer.

10. The semiconductor device according to claim 9, wherein the first and second resistance-variable material layers are made of a phase change material.

11. The semiconductor device according to claim 9, wherein the first and second resistance-variable material layers are made of perovskite-type metal oxide.

12. The semiconductor device according to claim 9, wherein the plurality of first leads comprises first and second alignments of first leads, the first and second alignments of first leads run in the first horizontal direction, and the ends of the first leads belonging to the first alignment face toward the ends of the first leads belonging to the second alignment, and
wherein the plurality of second leads comprises first and second alignments of second leads, the first and second alignments of second leads run in the first horizontal direction, and the ends of the second leads belonging to the first alignment face toward the ends of the second leads belonging to the second alignment.

13. A semiconductor device including a fuse structure, the fuse structure comprising:
a substrate configured to be applied with a reference power;
a resistance-variable material layer that extends over the substrate in a first horizontal direction, the resistance-variable material layer contacting the substrate;
an insulating layer over the resistance-variable material layer;
a plurality of leads over the insulating layer, each of the first leads extending in a second horizontal direction that crosses the first horizontal direction; and
a plurality of via contacts that penetrate the insulating layer, the plurality of via contacts connecting between the plurality of leads and the resistance-variable material layer.

14. The semiconductor device according to claim 13, wherein the resistance-variable material layer is made of a phase change material.

15. The semiconductor device according to claim 13, wherein the resistance-variable material layer is made of perovskite-type metal oxide.

16. The semiconductor device according to claim 13, wherein the plurality of leads comprises first and second alignments of leads, the first and second alignments of leads run in the first horizontal direction, and the ends of the leads belonging to the first alignment face toward the ends of the leads belonging to the second alignment.
